(19) United States
(12) Patent Application Publication
(10) Pub. No.: US 2024/0402262 A1
(43) Pub. Date: Dec. 5, 2024

(54) PORTABLE NMR APPARATUS AND SYSTEMS AND METHODS FOR ANALYZING NMR DATA OBTAINED THEREFROM

(71) Applicant: Rahner James, Orangevale, CA (US)

(72) Inventor: Rahner James, Orangevale, CA (US)

(21) Appl. No.: 18/734,279

(22) Filed: Jun. 5, 2024

Related U.S. Application Data
(60) Provisional application No. 63/506,361, filed on Jun. 5, 2023.
(60) Provisional application No. 63/569,839, filed on Mar. 26, 2024.

(51) Int. Cl. G01R 33/00; G01R 33/383; G01R 33/44

(52) U.S. Cl. CPC G01R 33/0047; G01R 33/0023; G01R 33/383; G01R 33/448

(57) ABSTRACT

Embodiments disclosed herein provide NMR systems and methods that use a portable, battery-powered, and robust NMR sensor apparatus to obtain NMR data of a sample, algorithms for evaluating the NMR data, and a user interface that presents specific, focused results of the NMR data analysis. The NMR systems and methods can be used to identify various physiological, chemical and health conditions in human, animals, plants and other biological materials. In addition, the NMR systems and method can also be used to identify chemicals, compounds, and elements in inorganic matter or non-biological substances.

### CROSS-REFERENCE TO A RELATED APPLICATION

This patent application claims the benefit of U.S. Provisional Patent Application No. 63/506,361, filed Jun. 5, 2023, and U.S. Provisional Patent Application No. 63/569,839, filed Mar. 26, 2024, the disclosures of which are incorporated herein in their entireties.

### TECHNICAL FIELD

This specification relates to a portable device utilizing Nuclear Magnetic Resonance (NMR) capability to detect organic compounds to be analyzed by an external computer or mobile device.

### BACKGROUND

Devices using NMR technology for chemical analysis have been in use since the 1950's. Desktop units using NMR technology have been available for the last 20 years. Conventional devices using NMR technology are expensive, non-ruggedized for use in the field, and unnecessarily complex for everyday use and require operation by trained technicians.

### BRIEF SUMMARY

Embodiments disclosed herein provide NMR systems and methods that use a portable, battery-powered, and robust NMR sensor apparatus to obtain NMR data of a sample, algorithms for evaluating the NMR data, and a user interface that presents specific, focused results of the NMR data analysis. The NMR systems and methods overcome the aforementioned limitations of complexity, inconvenience, and training requirements of conventional NMR systems. The NMR systems and methods can be used to identify various physiological, chemical and health conditions in human, animals, plants and other biological materials. In addition, the NMR systems and method can also be used to identify chemicals, compounds, and elements in inorganic matter or non-biological substances.

A further understanding of the development's nature, advantages and improvements of the embodiments discussed herein may be realized by reference to the remaining portions of the specification and the drawings.

### BRIEF DESCRIPTION OF THE DRAWINGS

FIG. 1 shows an illustrative electromagnetic (EM) transmitter of a portable NMR apparatus according to an embodiment.

FIG. 2 shows an illustrative EM receiver, switches and memory system of a portable NMR apparatus according to an embodiment.

FIG. 3 shows an illustrative control system of a portable NMR apparatus according to an embodiment.

FIG. 4 shows an illustrative computing system configured to process NMR data received from a portable NMR apparatus according to an embodiment.

FIG. 5 shows another illustrative computing system configured to process NMR data received from a portable NMR apparatus according to an embodiment.

FIG. 6 shows an illustrative data analysis engine according to an embodiment.

FIG. 7 shows another illustrative data analysis engine according to an embodiment.

FIG. 8 shows an illustrative system diagram of an NMR system according to an embodiment.

FIG. 9A shows an illustrative magnet array used in a portable NMR apparatus according to an embodiment.

FIG. 9B shows an illustrative cross-sectional view of a magnet array according to an embodiment.

FIG. 10A shows an illustrative antenna assembly used in a portable NMR apparatus according to an embodiment.

FIG. 10B shows an illustrative top view of an antenna assembly according to an embodiment.

FIG. 11 shows a partial exploded view of a portable NMR apparatus according to an embodiment.

FIG. 12A shows the logical diagram of the battery charge boost circuit that allows the transmitter to deliver up to one (1) kilowatt of power to the antenna according to an embodiment.

FIG. 12B shows a functional diagram of the components that make up the EM receiver of a portable NMR apparatus according to an embodiment.

FIG. 13 shows a flowchart for the software initialization of a portable NMR apparatus upon power up or when coming out of a power conserving sleep state according to an embodiment.

FIG. 14 shows a flowchart for the software process of a properly configured portable NMR apparatus in normal operation according to an embodiment.

FIG. 15 shows a flowchart for the software process of the Application Programming Interface (API) which would convert raw NMR data into an extensible format and combine that data with other data pertinent for its full analysis according to an embodiment.

FIG. 16 shows a flowchart for the software or hardware assisted process for analyzing the stored data from the API according to an embodiment.

FIG. 17 shows a flowchart for the process for using the audio acceleration hardware to augment the process for analyzing the stored data from the API according to an embodiment.

FIG. 18 shows a flowchart for the process for comparing specific NMR results with historical data to determine trends over time according to an embodiment.

FIGS. 19A and 19B show illustrative user interface screen shots according to an embodiment.

FIGS. 20A and 20B show additional illustrative user interface screen shots according to an embodiment.

FIGS. 21A-21C show more illustrative user interface screen shots according to an embodiment.

### DETAILED DESCRIPTION

The following description, taken in conjunction with the referenced drawings, is presented to enable one of ordinary skill in the art to make and use the development and to incorporate it in the context of particular applications. Various modifications, as well as a variety of uses in different applications will be readily apparent to those skilled in the art, and the general principles defined herein may be applied to a wide range of embodiments. Thus, the present development is not intended to be limited to the embodiments presented, but is to be accorded the widest scope consistent with the principles and novel features disclosed herein. Furthermore, it should be noted that, unless explicitly stated otherwise, the figures included herein are illustrated diagrammatically and without any specific scale, as they are provided as qualitative illustrations of the concepts presented herein.

One skilled in the art will appreciate that the scope of the terms is intended to be construed with reference to this disclosure as a whole and with respect to the claims below. In order to provide a working frame of reference, a brief introduction is provided in the form of a narrative description of the present development to give a conceptual understanding prior to developing the specific details. The introduction is followed by a detailed description to enable the reader to make and use the various embodiments of the development without involving extensive experimentation.

The ensuing description provides exemplary embodiments only, and is not intended to limit the scope, applicability or configuration of the disclosure. Rather, the ensuing description of the exemplary embodiments will provide those skilled in the art with an enabling description for implementing one or more exemplary embodiments. It being understood that various changes may be made in the function and arrangement of elements without departing from the spirit and scope of the development as set forth in the appended claims.

Specific details are given in the following description to provide a thorough understanding of the embodiments. However, it will be understood by one of ordinary skill in the art that the embodiments may be practiced without these specific details. For example, circuits, systems, networks, processes, and other elements in the development may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed, but could have additional steps not discussed or included in a figure. Furthermore, not all operations in any particularly described process may occur in all embodiments. A process may correspond to a method, a function, a procedure, a subroutine, a subprogram, etc. When a process corresponds to a function, its termination corresponds to a return of the function to the calling function or the main function.

The term “machine-readable medium” includes, but is not limited to portable or fixed storage devices, optical storage devices, wireless channels and various other mediums capable of storing, containing or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

Furthermore, various embodiments discussed herein may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

NMR systems and methods discussed herein use an NMR apparatus that can quickly evaluate a sample (e.g., body fluids such as urine, saliva, sweat, blood, excrement) of a human, animal (e.g., dog, cat, horse, cow), plant, other biological matter, non-biological matter, or inorganic matter to obtain a set of raw NMR data. In one embodiment, the apparatus can be a portable battery powered device that can generate a 1 kW pulse for 10 microseconds to obtain the NMR data set of the sample. The NMR apparatus can be a portable, self-powered device, capable of receiving a sample, subjecting the sample to EM energy to obtain the set of raw NMR data, and transmitting the set of raw NMR data to a remote device capable of further processing the raw NMR data. Offloading computationally heavy analysis of raw NMR data to a remote processing system enables the NMR apparatus to be simplified, ruggedized for field use (e.g., in a home environment), and cheaply produced. The portable apparatus can include a user interface (e.g., for controlling operation, displaying status of operation, or a combination thereof) and communications circuitry for communicating with a remote device. In some embodiments, the portable apparatus can pre-process the raw NMR data to provide a pre-processed NMR data set to the remote device. In some embodiments, the NMR apparatus may be configured with an AI-enabled edge processor or ASIC to analyze the raw NMR data and provide results thereof on the apparatus itself or to a remotely connected device. For example, in such an AI-enabled embodiment, the apparatus may be configured to detect a finite set of targets within the sample (e.g., confirm existence of Lithium in the sample).

The raw or pre-processed NMR data can be received by a remote device (e.g., a phone, tablet, computer, or backend computer server) that can apply a data analysis engine to the NMR data to transform and analyze the data to produce a useful result. In one embodiment, the received NMR data is transformed into another signal that is suitable for processing by a processor of the remote device (e.g., such as the audio processing CPU, or graphic processing unit, or general CPU). For example, the NMR data can be transformed into an audio signal.

The received NMR data can be transformed into a signal adapted to a particular evaluation template. For example, if the user wishes to evaluate the sample for diabetes, the transformed signal is adapted to a diabetes template and evaluated within the context of the diabetes template. The template can provide a specific filter set specifically designed to evaluate a transformed NMR data set to confirm whether a target assessment (e.g., a diabetes marker) is present in the sample. Multiple templates may be available, for example, for cardio informatics, exercise informatics, cancer informatics, viral diseases, bacterial diseases, neurological issues, drug assessment, element assessment, chemical assessment, compound assessment, gas assessment, solution assessment, etc., all of which may be user selected in a user interface. If desired, a user can import or use third party templates to analyze NMR data of a sample tested by a portable NMR apparatus.

As defined herein, Nuclear Magnetic Resonance (NMR) is a physical phenomenon in which nuclei in a strong constant magnetic field are perturbed by a weak oscillating magnetic field (in the near field) and respond by producing an electromagnetic signal with a frequency characteristic of the magnetic field at the nucleus.

A portable NMR apparatus refers to a device that uses NMR to obtain NMR data on a sample contained therein. The NMR apparatus can include a container, electronics, battery, power system, a magnet, an embedded processor, an antenna, communications circuitry, and all other components.

As defined herein, a magnet assembly represents a magnet configuration, a single magnet or a group of magnets arranged in a specific configuration, used in the NMR apparatus. The magnet assembly provides a strong, uniform magnetic field in which the target sample resides during a sample event. The magnet assembly can include, but is not limited to, a Halbach Array or a set of parallel magnetic plates.

As defined herein, a remote device can represent any external computing device that receives data from the NMR apparatus. For example, a remote device can include cell phones, tablets, laptops or any other programmable computing device.

As defined herein, an analysis engine refers to hardware, software, or combination thereof for analyzing NMR data. The analysis engine may analyze NMR data according to an evaluation template.

As defined herein, an evaluation template can define how NMR data is analyzed. The template can contain, but is not limited to, configuration information, user interaction definitions, filtering descriptors to eliminate various the NMR response data that is not required for the template's analysis, scoring descriptors to weigh the various characteristics of NMR response data, fingerprinting descriptors that determine a targeted result or results from scores calculated. Template and their descriptors can be a combination of static and dynamic configurations values and ranges in text or binary form. Operational code can be in the form of scripts, programming languages, including, but not limited to, Python, Java, HTML, or native binary executable code. Language/voice/audio data can be used by hardware accelerators within a computer.

As defined herein, an Application Programming Interface (API) can support the accessibility of a third party to provide additional software or hardware programming to make use of the data provided by the NMR device and data provided by the analysis engine. For example, the analysis engine may access the API to access a third party evaluation template.

As defined herein, electromagnetic (EM) signals can represent any Electro-Magnetic or Radio Frequency generation or detection used by the NMR apparatus.

As defined herein, a user interface (UI) can represent any aspect of the conveyance of information to a user including, but not limited to, visual, auditory, tactile, and the mechanisms by which a user controls or interacts with the NMR apparatus and/or the remote device.

As defined herein, near field communication (NFC) can represent any near field communication including, but not limited to, inductive power mechanisms.

Any communication mechanism used to transmit information/data between the NMR apparatus and the remote device. For example, any form of radio frequency communication including, but not limited to, WiFi, 802.11, Bluetooth, NFC, or infrared communication, can be used. In addition, any physically cabled communication method including, but not limited to, USB, RS-232, I2C, SPI, PCI can be used.

An analog to digital converter (ADC) be used to represent all methods or devices that convert analog signals into a digital representation of that signal including, but not limited to, Analog to Digital Converter components and circuits;

As defined herein, spread spectrum relates to an EM signal that includes multiple adjacent frequencies.

As defined herein, batteries shown within all figures can be physical batteries, chargeable or non-chargeable including, but not limited to, Nickel-Cadmium (NiCad), Lithium Ion (Lithium), Lithium Polymer (LiPo), Lead acid types; or some other supplier of power for the embodiment including, but not limited to, inductive power, solar cells, cabled power units.

An NMR system can include the NMR apparatus and the remote device, power techniques, communication methods, all software, circuitry, hardware, and user interfaces.

As defined herein, sample can refer to the compound that is placed within the NMR apparatus and subjected to an NMR application event.

In one embodiment, a portable NMR apparatus is an inexpensive, portable, battery powered, molecular analysis device that uses NMR technology to determine the physical and/or metabolic state or composition of a sample (e.g., human or animal effluence (saliva, blood, urine, etc), any organic compound, plant matter, or inorganic matter (e.g., soil, gas, rock)). The portable NMR apparatus can rely on the remote device to process, analyze, and present results on NMR data derived from an NMR application event. The portable NMR apparatus uses permanent magnets, charge pumps, and power control methods to generate and subject a sample with unique EM signals that incites a response thereto and which is captured (received) as NMR data. This NMR data can be converted using data transform techniques that enable the use of the audio acceleration capabilities of a remote device to enhance the analysis performance of the NMR data. The results of the analysis can be presented in a simplified form (e.g., marker is present or not present in the sample), thereby eliminating the need for a highly trained individual to analyze complex data sets typically produced by conventional NMR systems. For example, in one embodiment a home user can use the NMR apparatus to test a sample of his or her saliva, blood, or organic matter. The data from the test can be sent to the user's phone, which executes an analysis engine on the data to detect and quantify presence or absence of organic molecules indicative of specific physical and metabolic conditions, and presenting the results on the user's phone. The analysis engine may use an evaluation template (e.g., either a native template or a third party template) to evaluate the NMR data in the context of specific evaluation criteria to provide a specific and concrete result to the user.

The software and/or hardware operating on the remote device can be adapted to receive NMR data from NMR devices that are produced by third parties. Such third parties may be required to package the NMR data in a format amenable for an analysis engine such that data can be properly evaluated. The third party device may make use of an API to upload data to a remote device.

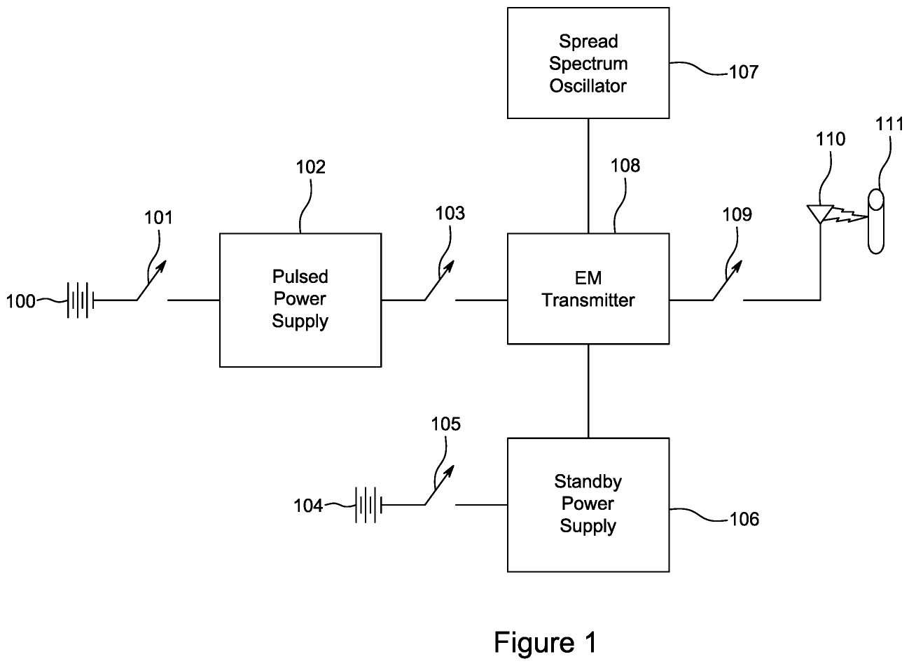

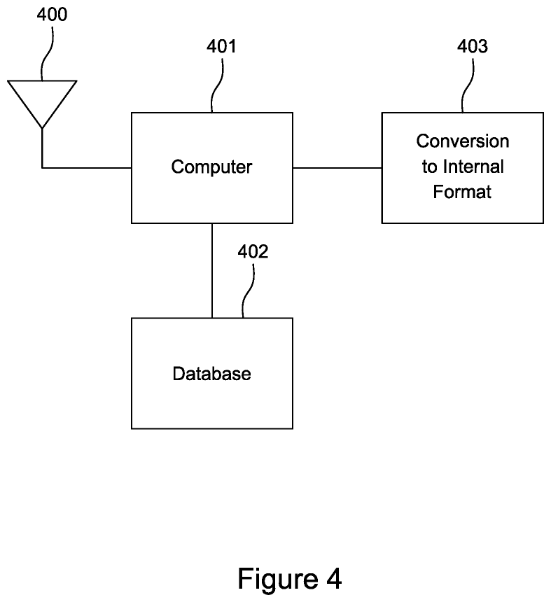

FIGS. 1-3 show different functional block diagrams of a portable NMR apparatus according to an embodiment. FIGS. 4-7 shows different functional block diagrams for processing and analyzing data received from the NMR apparatus. FIGS. 4-7 may be implemented in a device other than the portable NMR apparatus. It may be desirable to offload the processing and analyzing operations from the portable NMR apparatus to keeps cost as low as possible and to maintain the NMR apparatus as a rugged and reliable field use device.

FIG. 1 shows an illustrative electromagnetic (EM) transmitter of a portable NMR apparatus according to an embodiment. First battery 100 can be connected to switch 101, to reduce power consumption, and is used to energize pulsed power supply 102. Pulsed power supply 102 can increase the voltage from first battery 100 and charges a bank of capacitors to provide over 10 millijoules (>1 kilowatt) of energy to EM transmitter 108. Second battery 104 can be connected to switch 105, to reduce power consumption, and is used to provide power for standby power supply 106, which reduces the power up latency of EM transmitter 108. In some embodiments, first battery 100 and second battery 104 are the same. When both pulsed power supply 102 and standby power supply 106 are fully powered, EM Transmitter 108 amplifies the signal from Spread Spectrum Oscillator 107 and that amplified signal is gated into antenna 110 by switch 109. EM transmitter 108 imparts an EM signal into sample 111. Oscillator 107 is used to compensate for any flux strength variance within the magnetic chamber due to the use of a permanent magnet. The EM pulse excites the sample contained within the magnetic chamber. Switch 109 can disconnect EM transmitter 108 from antenna 110 after a timed period and the entire transmitter assembly is disconnected by switch 103 and powered off using switches 101 and 105.

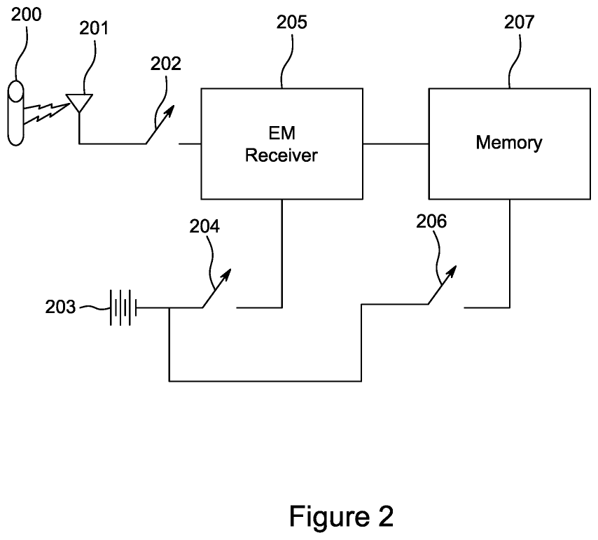

FIG. 2 shows an illustrative EM receiver of a portable NMR apparatus according to an embodiment. Battery 203 can supply power EM receiver 205 and memory system 207 using switches 204 and 206. In some embodiments, battery 100, 104, and 203 can all be the same battery. EM receiver 205 can be connected to antenna 201 through switch 202 and detects the relaxation energy emanations of the sample 200. EM receiver 205 can apply filters, amplifiers, and a mixer to convert the signal to an appropriate frequency that is then converted to digital data by an Analog-to-Digital Converter (ADC). That converted data can then be stored in memory system 207. A person skilled in the art understands that data can be stored in a variety of ways for performance or memory efficiency.

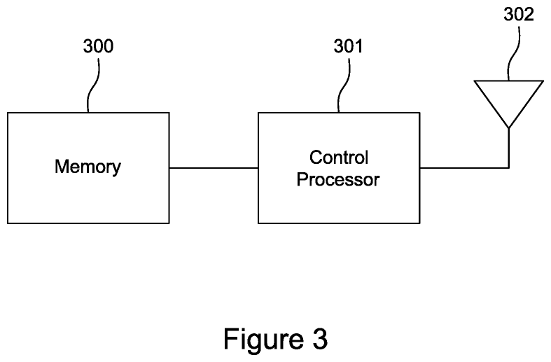

FIG. 3 shows an illustrative control system of a portable NMR apparatus according to an embodiment. Control processor 301 can obtain the digital data stored in memory 300 (or memory 207 of FIG. 2) and transmit the data to a remote device using a wireless connection, an infrared connection, or a wired connection. In this figure, an antenna 302 is shown, which can include, but is not limited to, WiFi, Bluetooth, LoRa, NFC or any wireless communication method. A person skilled in the art could easily replace that wireless mechanism with a wired mechanism which can include, but is not limited to, USB, Ethernet, RS-422, RS-232, SPI, I2C.

The fundamental principal on which the NMR apparatus is based is the linear relationship between magnetic field strength and the frequency at which protons in certain atoms resonate. The relationship between the resonant frequency and the magnetic field strength is linear and is expressed as: μ=γI, where μ is the resonant frequency, I is the magnetic field strength and γ is gyromagnetic ratio with units of Megahertz/Tesla (MHz/T). The protons of the most common isotope of hydrogen atoms (1H) are the initial targets for the development due to their existence in virtually all organic compounds; although, it will be recognized by those of skill in the art that the development could be used to detect other atoms such as but not limited to, carbon-13 and phosphorus-31. The gyromagnetic ratio for ¹H is 42.576 MHz/T, so μ=42.576×I. At the resonant frequency of the protons, their spin flips. Those energized protons reradiate that stored energy in two relaxation steps: the first within milliseconds and the second within seconds. Due to the time for that second relaxation period, subsequent excitation of a sample is not done until after the second relaxation period has elapsed. The receivers in the embodiment can sense the EM energy from either relaxation state.

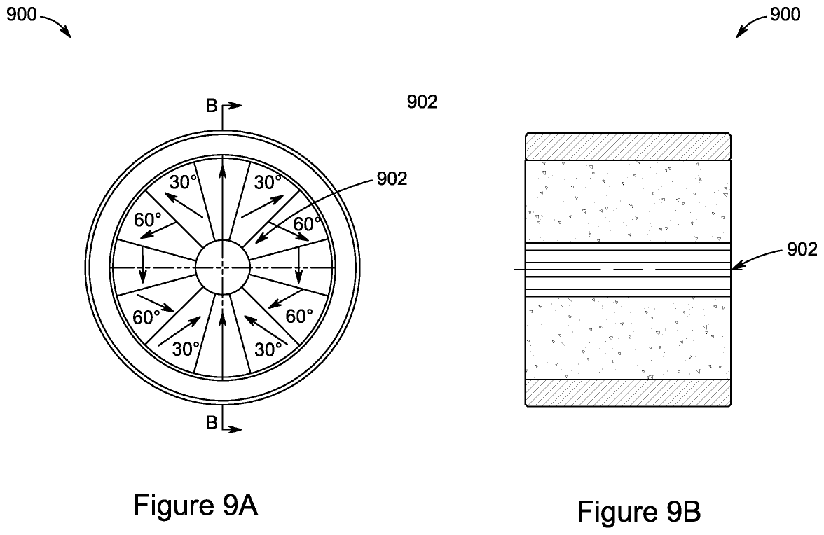

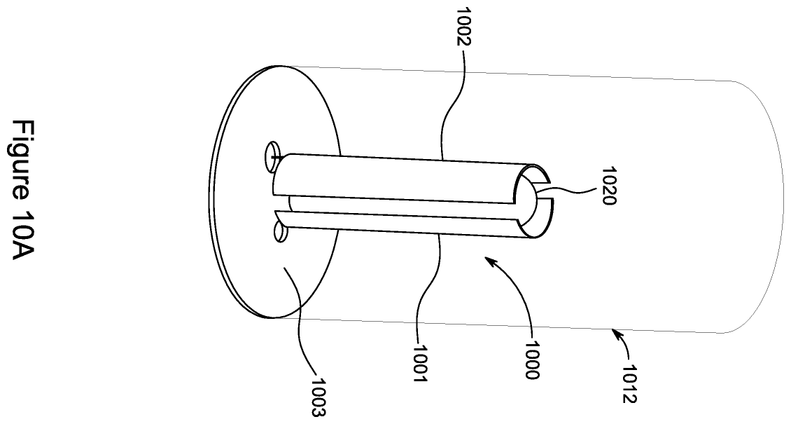

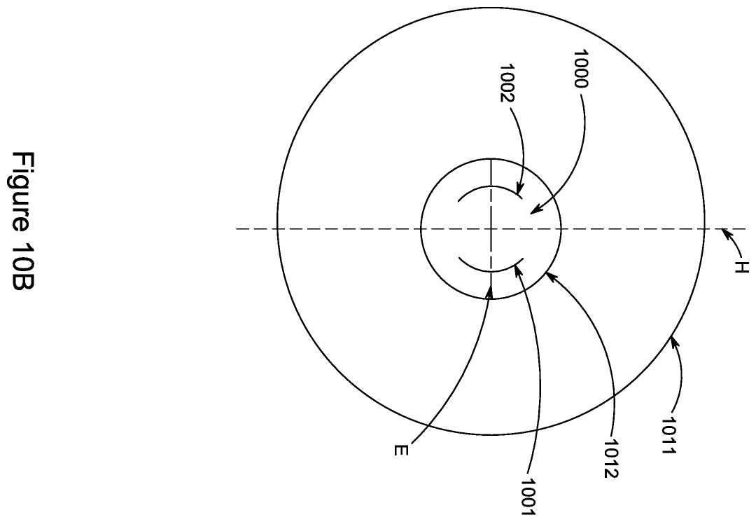

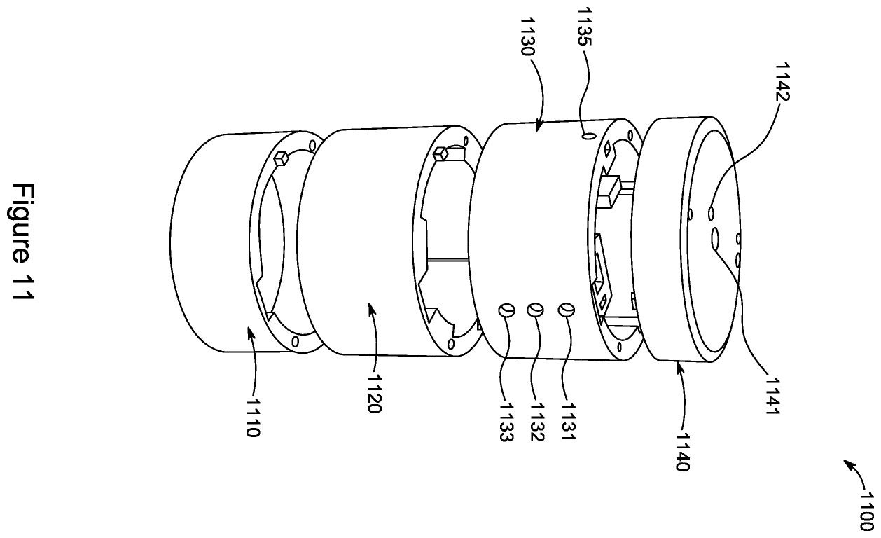

NMR requires a strong uniform magnetic field to align the spin of hydrogen protons. In one example, permanent magnets arranged as a Halbach Array magnet 900 (shown in FIGS. 9A and 9B) can create a strong, uniform magnetic field within the open cylindrical center 902. FIG. 9A shows an illustrative top view of a halfback array magnet and FIG. 9B shows an illustrative cross-sectional view taken along line B-B of FIG. 9A. It should be recognized by those of skill in the art that other configurations can be used, such as, but not limited to, a Halbach Array having a different number of magnetic sections, a different width or a non-Halbach Array such as a pair of separated parallel magnetic plates. Open cylindrical center 902 is sized with sufficient diameter to accommodate an antenna assembly (shown in FIG. 10A) and the container (also shown in FIG. 10A) holding the sample to be analyzed. In any example of a permanent magnet configuration, the geometry is selected so that the magnetic field outside the assembly is minimized to reduce any negative effects of a strong magnetic field interacting with objects outside the container. It should be recognized by those of skill in the art that other center sizes or shapes can be used. The open cylindrical center 902 may also be of sufficient height to fully align as many targeted protons in the sample for the highest fidelity results. It should be recognized by those of skill in the art that other heights of the magnetic assembly, either lower or higher than that shown in FIGS. 9A and 9B, can be used. FIG. 9A shows the layout of a permanent magnet in one possible configuration of a Halbach Array, which is one example of a magnet assembly that can provide a strong, uniform magnetic field. Particularly, the magnetic field has its highest concentration in a direction across open cylindrical center 902. For example, the direction of the magnetic field may be aligned between 0 and 180 degrees across center 902. It should be recognized by those of skill in the art that other configurations could be used, such as, but not limited to, a Halbach Array of different dimensions or a different magnet section count, or two or more parallel magnetic plates separated to allow the insertion of a sample.

An antenna assembly 1000, as illustrated in FIGS. 10A and 10B, can be placed inside the open cylindrical center 1012 (shown in FIG. 10B) of magnet 1011 and sample vessel 1020 can be positioned within antenna directors 1001 and 1002. Antenna assembly 1000 is used is energized to impart EM signal to and detect emissions re-radiated from the sample contained in the sample vessel 1020. In some embodiments, sample vessel 1020 may be a test tube having a diameter and a length and is configured to retain a sample therein. Sample vessel 1020 is designed to fit within spacing defined by antenna directors 1001 and 1002, which collectively form an antenna array. As shown, antenna directors 1001 and 1002 each exhibit a curved geometry having a radius that is slightly larger than the radius of the sample vessel 1020. Antenna directors 1001 and 1002 face each other but do not touch each other and extend for a fixed length within open cylindrical center 1012. FIG. 10B shows an illustrative top view of magnet 1011 and antenna directors 1001 and 1002. In this view, antenna directors 1001 and 1002 can collectively form a hollow columnar antenna array with a gap existing between each half of the array. A cross-section of the hollow columnar antenna array may resemble a circle with a centerline cutout or two curved shapes that approximate a circle. Moreover, antenna directors 1001 and 1002 are arranged such that the EM field, E, generated by the antenna array is substantially orthogonal to the magnetic field, H, flux lines provided by magnet 1011. This arrangement maximizes efficiency of the NMR effect of the portable NMR apparatus.

Antenna assembly 1000 is used to energize the sample with an EM pulse for a period of time that is configurable (default setting is approximately ten (10) microseconds). It should be recognized by those of skill in the art that other pulse durations can be used. The pulse duration can be determined by a configuration setting of the control processor to achieve optimal quality of NMR data. The duration configuration allows the user to achieve a balance between a longer time which may reduce the fidelity of the result or a shorter time which would reduce the sample saturation causing an attenuation of the sample relaxation emanation power. Antenna assembly 1000 can be mounted on the back side of transmitter circuitry 1003 with all organic compounds stripped from the copper foil of that side. The copper is separated from the magnet assembly by a brass or stainless steel sheet to eliminate a redox reaction between the copper and the iron elements of the magnet and to maintain a good electrical connection with the circuit board. The use of copper, brass, and stainless steel within or near open cylindrical center 1012 is due to their non-magnetic nature to not alter the shape or direction of the magnet's flux.

In one embodiment, the diameter formed by antenna directors 1001 and 1002 can be around 7 mm, sample vessel 1020 can have a diameter of about 5 mm, and open cylindrical center 1012 can have a diameter of about 20 mm. These dimensions are merely illustrative and may change based on the strength of the magnet and size of the sampling vessel. In some embodiments, the Halbach array magnet 1011 currently range between 1.4 Tesla and 3.0 Tesla; although, new magnetic materials developed in the future would increase that magnetic flux strength.

FIG. 11 shows an illustrative housing 1100 for an NMR apparatus according to an embodiment. Housing 1100 is shown to be segmented in four different sections designed to interconnect with each other to form a compact, hand-held, device. Housing 1100 can include, from bottom to top, antenna assembly housing 1110, magnet assembly housing 1120, motor and display housing 1130, and communications and battery housing 1140. Each housing segment can be fabricated from a nonmagnetic material and is of a sufficient thickness so that the magnetic field expressed outside the container is reduced. Antenna assembly housing 1110 may securely hold an antenna assembly (e.g., antenna assembly 1000) in place such that the antenna directors are positioned within an open cylindrical center 1012 of a magnet assembly (e.g., magnet 900). The magnet assembly can be secured within magnet assembly housing 1120. The design of housing 1120 can allow for magnet assemblies of different dimensions or configurations to be used without the need to redesign housing 1100.

Motor and display housing 1130 may contain a motor assembly configured to rotate a sample vessel (not shown) that is inserted into the NMR apparatus. Housing 1130 may include display lights 1131-1133 and button 1135. Display light 1131 may indicate whether power is ON and the device is ready for operation. Display light 1132 may provide status of a sampling event (e.g., with a red light equal to a sample event failure, yellow light equal to sample event in process, and green light equal to a successful sample event). Display 1133 may indicate status of wireless communications (e.g., whether the WiFi or Bluetooth connection is good, connecting, or bad). Button 1135 may be a user depressible switch that can instruct the NMR apparatus to acquire NMR data from a sample.

To maximize the saturation of the target protons and the homogeneity of the saturation, the sample can be spun using a small motor housed within housing 1130. Upon activation of the NMR process, the sample vessel (e.g., a thin glass tube) is pressed against a wheel attached to the motor's shaft. When the motor spins, the wheel turns and rotates the sample vessel. Housing 1130 is sized to ensure that sufficient special separation exists between the motor and the magnet assembly so that the motor can function properly. It should be recognized by those of skill in the art that there are many other methods for spinning a sample. Another version of the development can eliminate the motor and the ability to spin the sample. This version may reduce the fidelity of the sample results, but eliminates the cost and complexity of the spinning mechanism.

Communications and battery housing 1140 can secure communications circuitry for transmitting data to a remote device and for securing batteries. Housing 1140 can include a threaded through-hole 1141 for receiving the sample vessel therein and a button 1142 that is depressed when a cover (not shown) is screwed into threaded through-hole 1141. Button 1142 may serve as an on/off switch for the NMR apparatus. The cover (not shown) may be screwed into the hole 1141 to prevent objects (especially magnetic objects) from entering the NMR apparatus. When the cover is present, the button may be depressed, which turns OFF the NMR apparatus. When the cover is removed, the button may be released, which turns ON the NMR apparatus. In addition, when the NMR apparatus is ON and hole 1141 is not covered a sample vessel can be inserted into the NMR apparatus via hole 1141.

The sizing and spatial arrangement of housing segments 1110, 1120, 1130, and 1140 is such that the magnetic flux is not able to affect operation of various components contained in the NMR apparatus. For example, the communications circuitry contained housing 1140 is spaced sufficiently away from the magnet assembly to avoid interference with the flux emanating therefrom. In addition, the vertical height of housing 1110 may be selected to ensure that the magnetic field emanating out of the bottom of housing 1100 does not exceed a certain threshold. In some embodiments, the vertical heights of housing 1130 and 1140 may also be selected to ensure that the magnetic field emanating out of the top of housing 1100 does not exceed a certain threshold. The communications circuitry can be located in the top housing section of the apparatus to reduce the interference with the EM processing that is contained the lowest housing section. In some embodiments, a motor assembly is not required. In such embodiments, housing 1130 can include display lights and the user activated switch, but no motor assembly. In an alternative approach, housing 1130 can be eliminated and the display lights and user activated switch can be integrated into housing 1140.

The different sections of apparatus 1100 are designed so that any one of them can be altered without the need to redesign any of the other sections. A slot down the side of each segment allows a system backplane bus board to be used within that slot to reduce wire management, which simplifies construction of the container.

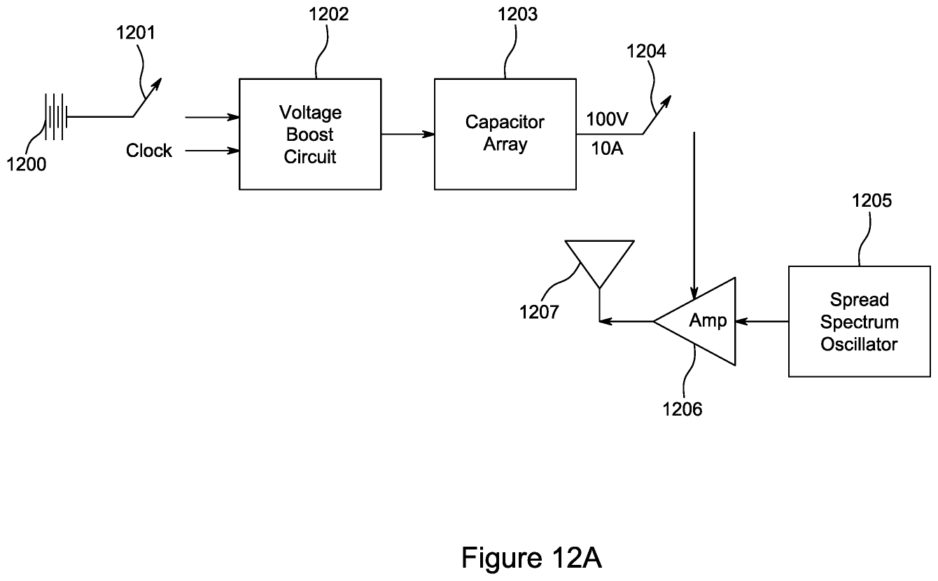

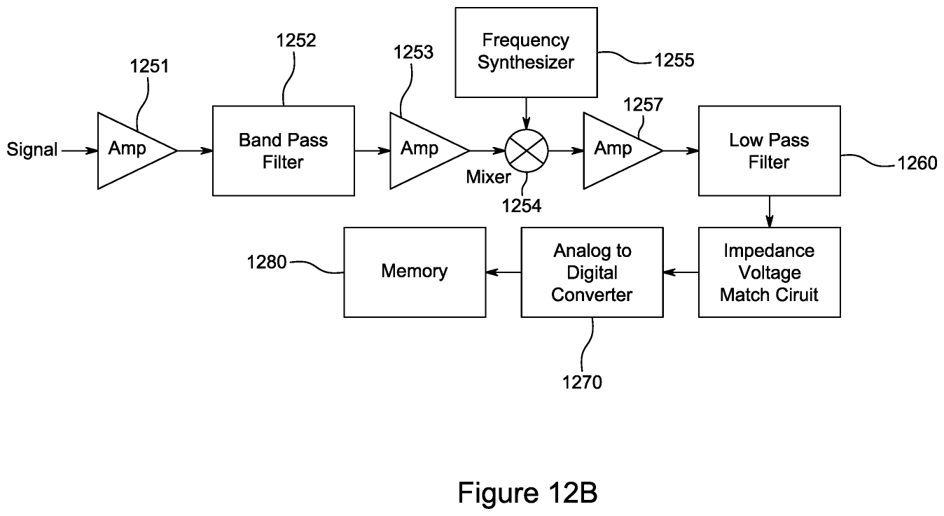

FIG. 12A shows a more detailed view of an EM transmitter circuitry according to an embodiment. The EM transmitter circuitry can include power source 1200, switch 1201, voltage boost circuit 1202, capacitor array 1203, switch 1204, spread spectrum oscillator 1205, EM transmitter 1206 (e.g., an amplifier), and antenna array 1207. The operation of the EM transmitter circuitry is similar to that described in connection with FIG. 1. The main difference between FIG. 1 and FIG. 12 is the addition of voltage boost circuit 1202 and capacitor array 1203. Voltage boost circuit 1202 is connected to power source 1200 via switch 1201 and is clocked by a clock signal to charge a bank of capacitors in capacitor array 1203. Capacitor array 1203 is used to provide a relatively high voltage (e.g., 100 volts), by drawing minimal current from power source 1200, to EM transmitter 1206. Using a high voltage EM transmitter (as opposed to a high current EM transmitter) enables the NMR apparatus to be portable and battery powered. EM transmitter 1206 can be a sine wave oscillator tuned to the approximate resonant frequency relative to the magnetic strength (μ=42.576×I). For example, the resonant frequency for ¹H in a magnetic field strength of 1.5T is 63.864 megahertz. It should be recognized by those of skill in the art that the variance in environmental issues, such as temperature, can cause a variance if the field strength of permanent magnets. To compensate for that variance, one example is to mix a set of secondary signals with a resonant frequency using spread spectrum oscillator 1205. The combination of frequencies is amplified using boosted voltage (e.g., 100 volts) provided by voltage boost circuit 1202 and capacitor array 1203) such that, for example, at least 10 millijoules of EM energy (˜1 kilowatt) is used to excite the protons of the sample. In some embodiments, the energy of the EM signal being applied to the sample may range between 0.1 kilowatt and 1.0 kilowatt. Limiting the energy to around 1 kilowatt may be desired based on the antenna design (e.g., the shape and size of the antenna) to prevent arcing. In another example, the resonant frequency of the magnetic flux strength can be determined by transmitting an EM pulse at a generated frequency by iteratively changing with a control processor until a control sample emanates a relaxation emanation. Yet another example is to determine the resonant frequency of the magnetic flux strength is to transmit a sample spectrum EM pulse, then detect the frequency of the sample's relaxation emanation, then transmit that specific frequency after the sample sends out its second relaxation emanation. It should be recognized by those of skill in the art that the power of the EM pulse transmitted can be varied to yield the same or different results. It will be recognized by those of skill in the art that the method for determining the magnetic flux strength could be performed using a variety of techniques. Another example to determine the resonant frequency of the magnetic flux strength is to use a spread spectrum EM transmitter coupled with a temperature sensor during the manufacturing process to determine the optimal resonant frequency of the magnet assembly through a wide set of temperatures as a thermal calibration definition, then store those values in the persistent memory of the controller. The spread spectrum EM transmitter can be replaced after calibration with a frequency synthesizer or other resonator which can use the thermal settings to transmit an EM pulse at the optimal resonant frequency. It should be recognized by those of skill in the art that the frequency synthesizer or resonator used for the EM receiver can also be used for the EM transmitter.

Due to the fact that the fidelity of the transmitted EM pulse is not of paramount importance, and the fact that the pulse duration is very short relative to the amount of time required to damage a semiconductor due to thermal extremes, and the fact that the secondary relaxation state of a sample requires seconds which allows cooling of overdriven circuitry to cool, it is not necessary to use circuitry that is rated at the maximum power level of the EM pulse. This enables smaller and less expensive components to be used.

During a sampling event, the EM transmitter is activated for a first period time and after the first period of time elapses, the EM transmitter is switched off via switch 1204 and the antenna array is also disconnected from the EM transmitter. It may be desirable for the antenna array to be disconnected within a fixed period of time (e.g., 60 nanoseconds or less) after the power to the EM transmitter has been turn off. After the EM transmitter is powered off and the antenna array is disconnected from the EM transmitter, a receiver (shown in FIG. 2) is powered on and connected to the antenna within a fixed period of time (e.g., 10 microseconds) after the EM transmitter has been powered off and disconnected from the antenna. The timing of powering the transmitter off, disconnecting the antenna from the transmitter, and power the receiver on, and connecting the antenna to the receiver eliminates the possibility of the transmitter damaging the receiver and provides an accurate timing of the first relaxation period from the sample. It will be recognized by those of skill in the art that the exact timing of this sequence can be altered without significantly affecting the results of the data from the sample.

FIG. 12B shows a more detailed view of receiver circuitry according to an embodiment. The receiver can amplify received EM signals (with amplifier 1251) to provide a first amplified signal. The first amplified signal can be filtered by band pass filter 1252 to provide a first filtered signal. The first filtered signal can be amplified using amplifier 1253 to produce a second amplified signal. The second amplified signal can be mixed at mixer 1254 with a predetermined frequency set by a control processor or frequency synthesizer 1255 to reduce the frequency of the received EM signals to below ten (10) kilohertz. The received EM signal exists at a fixed frequency (e.g., 74.0 MHZ) and the predetermined frequency (e.g., 74.1 MHz) is set near to the fixed frequency of the received EM signal such that the difference between the fixed frequency of the received EM signal and the predetermined frequency is passed to amplifier 1257. This differential signal can exist 10 kHz or below. Low pass filter 1260 can be applied to the differential signal to eliminate any interfering high frequency noise, providing a third filtered signal that can be converted to a digital signal with analog to digital converter 1270 and stores the digitized result in memory 1280. It will be recognized by those of skill in the art that any of the steps in that process could be altered using, not limited to, different levels of amplification, different durations for connections and disconnections, band pass filters of a different order, combinations of low pass and high filters, mixer/frequency synthesis combinations, signal generators other than frequency synthesizers, components for converting the analog signal to a digital representation, transmitting the analog signal to another system for external processing, transmission of the digital result rather than storing it into a local memory system, processing the digital data immediately, or converting the digital result immediately using a process such as a Fourier transform.

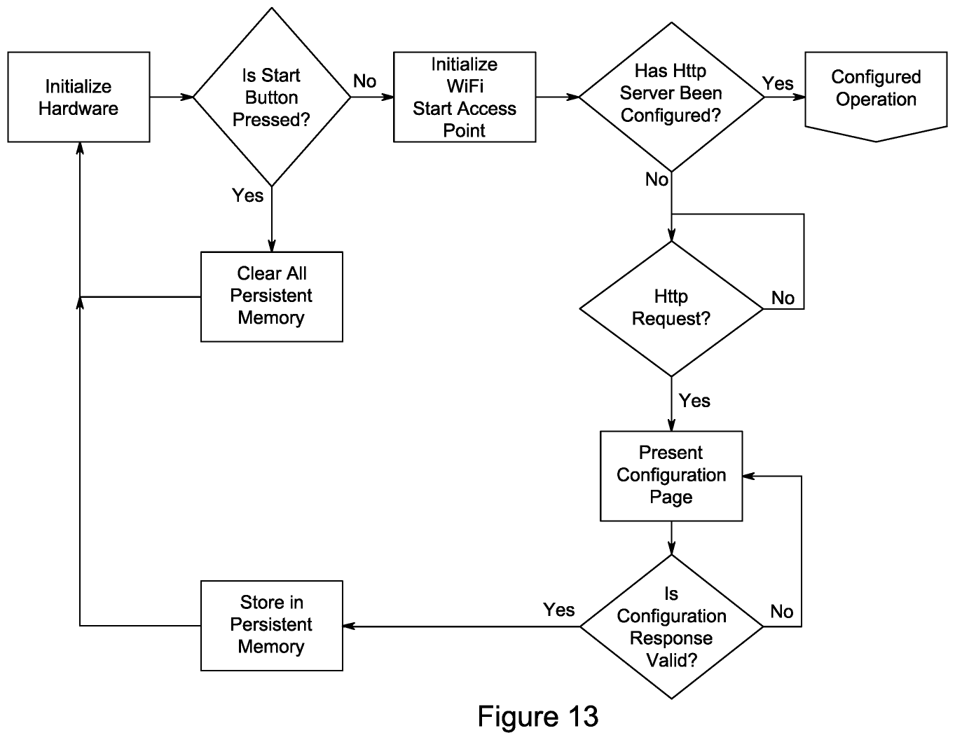

FIG. 13 shows a flowchart for the software initialization of a portable NMR apparatus upon power up or when coming out of a power conserving sleep state according to an embodiment. To address the desire of the user to maintain privacy of the data gathered, a configuration process can be used to allow the user to encrypt any data that would be transmitted from the unit to a remote device. It should be recognized by those of skill in the art that there are many methods to secure data including, but not limited to, encrypting data within the embodiment's memory, encrypting data once stored on the remote device, encrypting the communication between the embodiment and the remote device using standard encrypted protocols or some other method of communication obfuscation.

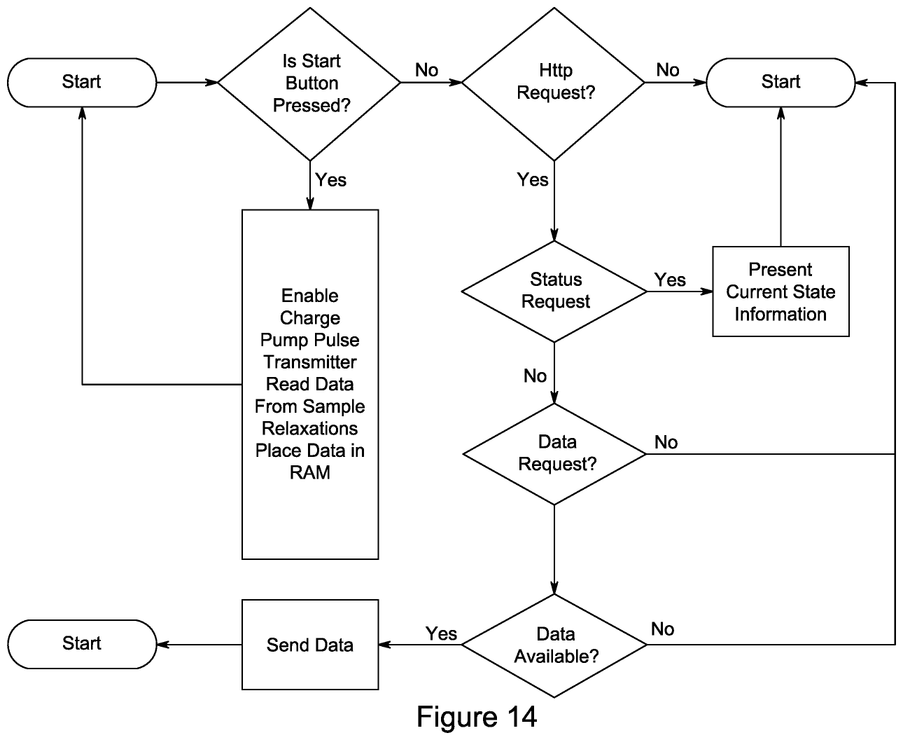

FIG. 14 shows an illustrative flowchart for the software process of a properly configured portable NMR apparatus in normal operation according to an embodiment illustrative After results have been stored in memory, the control processor signals can cause an LED light to turn ON to notify a user that that the sample is ready for transmission to a remote device. The control processor can turn ON another LED to show that a link to a remote device is active and ready to transmit via Wifi, Bluetooth, other wireless communications method. It should be recognized by those of skill in the art that there are many other communication methods that could be used, including, but not limited to, USB, LoRa or some NFC signaling method. If the control processor uses WiFi, it presents itself as both an access point (AP) and as a supplicant and allows the remote device to access the data using encrypted HTTP or any other encrypted network protocol.

FIG. 4 shows one example of remote device 401 or mobile device, which receives digitally encoded NMR data through communication conduit 400 from an NMR apparatus (not shown). Remote device 401 can use a database 402 of NMR definitions to convert the received digital data using an Application Programming Interface (API) into a representative internal format 403, which puts the data in a format more amenable to analyzing the data. It should be recognized by those of skill in the art that remote device 401 can be an Internet or network connected device or Cloud device that can be used to process the data received through this mechanism.

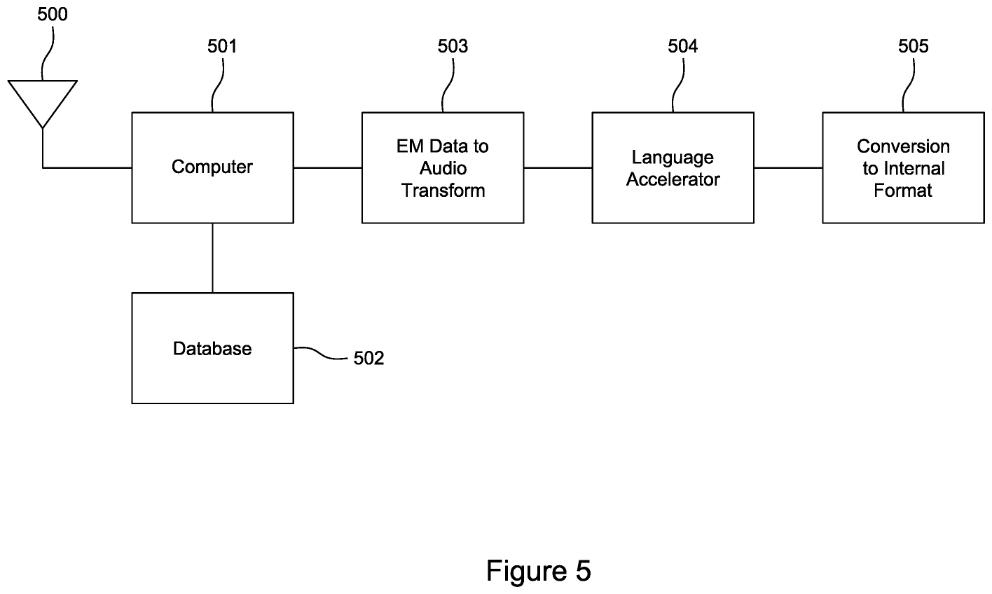

FIG. 5 shows another example of a remote device that processes NMR data obtained by an NMR apparatus according to an embodiment. Computer 501 or mobile device can receive the NMR data through communication conduit 500 (e.g., an antenna). Computer 501 can use database 502 of NMR definitions to convert the received data into a form resembling audio data using an NMR Data to Audio Transform 503. The data, in its audio format, can be sent to a language acceleration processor 504, along with a language definition template, to process the data signals into pre-filtered results that best represent the physical and/or metabolic state or composition of the sample. These pre-filtered results can be converted into a representative internal format 505, which is ultimately used to augment the analysis of the data. The NMR data received from the NMR apparatus may resemble signals operating in an audio spectrum and as a result, the signals are amenable to further processing by audio processing processors, audio transforms, and audio processing algorithms.

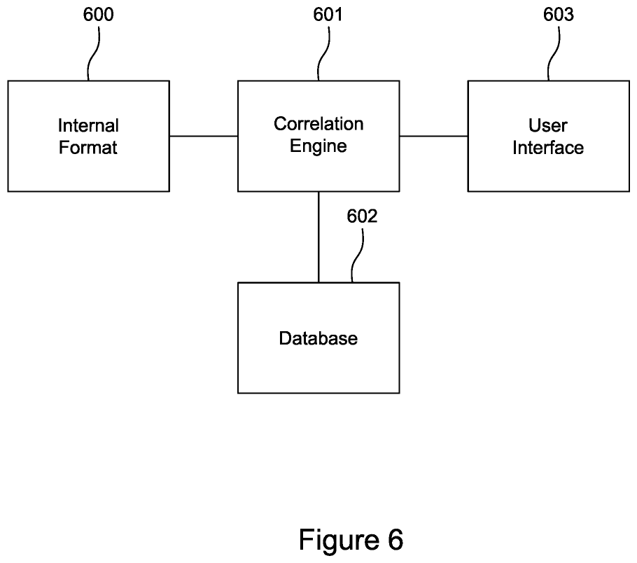

FIG. 6 shows an illustrative data analysis engine according to an embodiment. The correlation engine 601 can analyze Internal Formatted data 600 (e.g., data 403 or 505) with respect to data in stored database 602 to generate results for a specific condition (e.g., metabolic condition). Correlation engine 601 may be designed to identify specific data characteristics in internal formatted data 600 and assign a confidence factor to the identified data characteristics, if any. For any given characteristic to be identified, correlation engine 601 can be provided with a template (from database 602) that is specifically designed to identify that given characteristic. In some embodiments, it may be possible to apply the internal formatted data to many different templates for just one sample set and display the results for each template on user interface 603.

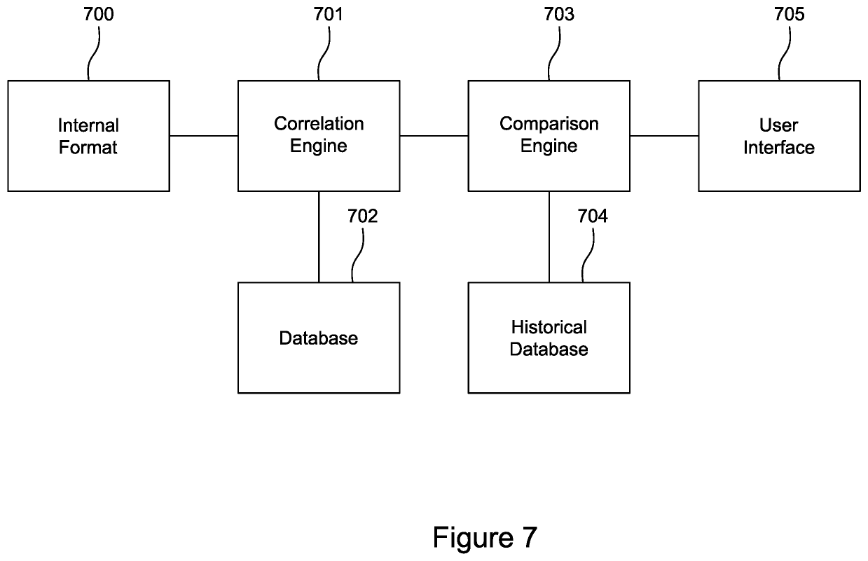

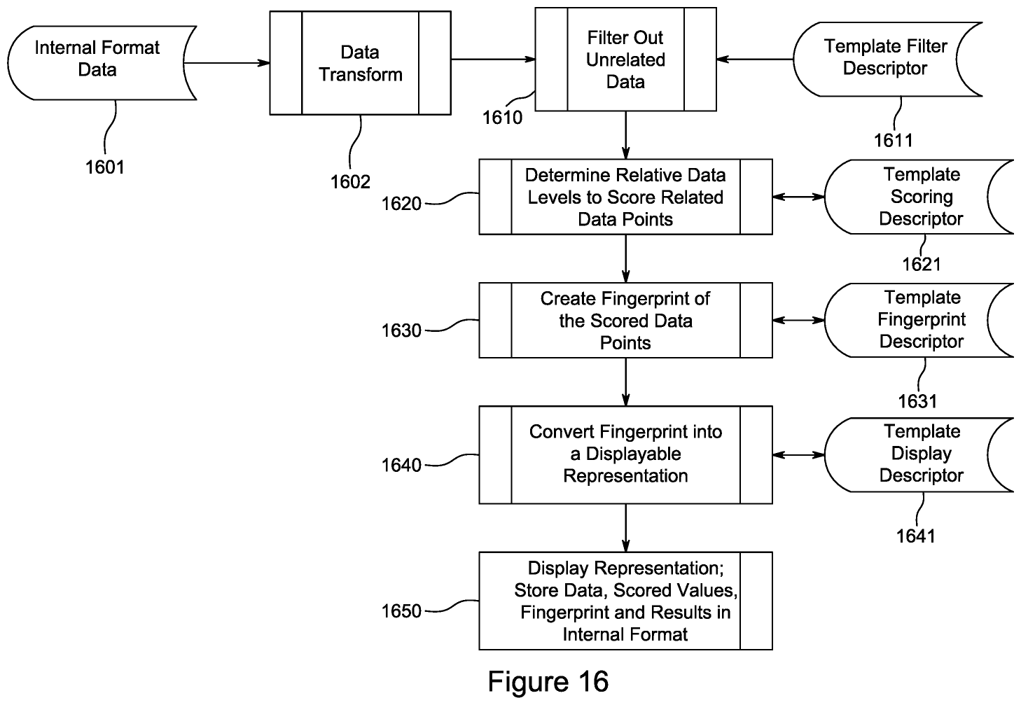

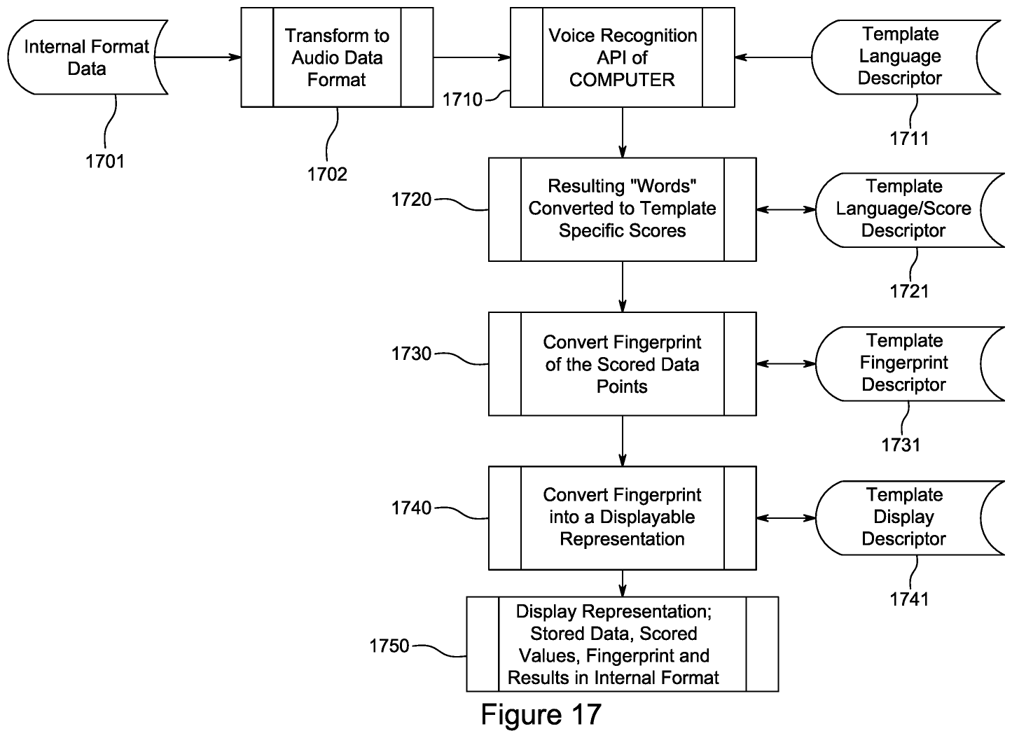

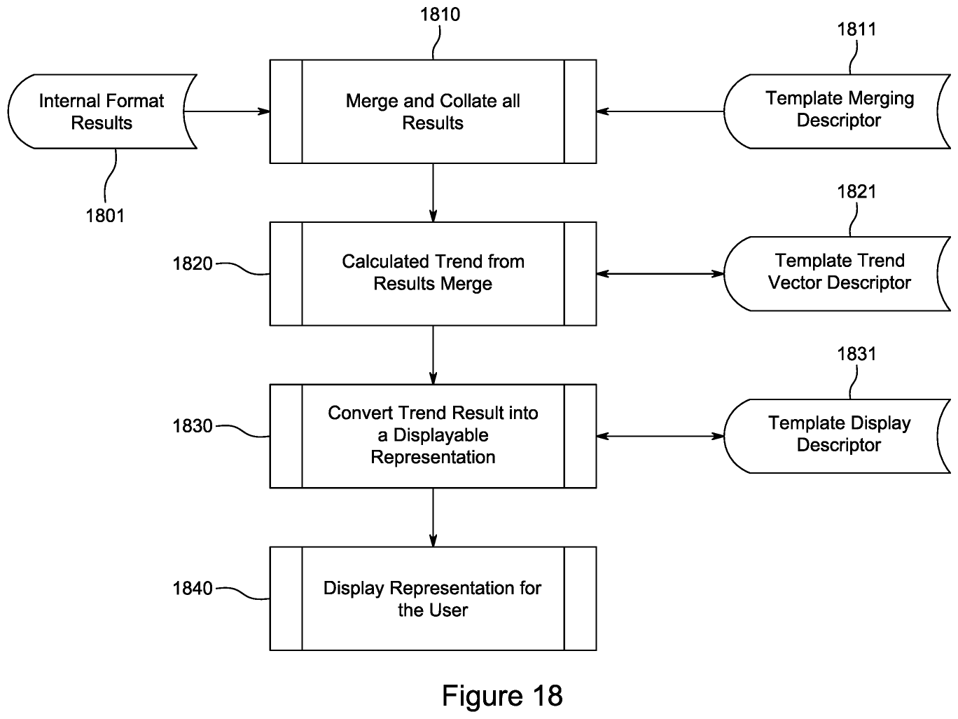

FIG. 7 shows another example of a data analysis engine. Correlation engine 701 can analyze the Internal Formatted data 700 (e.g., data 403 or 505) based on one or more templates and present those correlations to a user. Database 702 can contain specific condition information (e.g., metabolic conditions) which is used by Correlation Engine 701. The correlated data can then be passed to a Comparison Engine 703 which incorporates information from a Historical Database 704 to measure differentials (e.g., metabolic differences) for a subject or group of subjects. Comparison engine 703 may be used to determine trends in data for one or more template targets. The specific results can be displayed on user interface 705. In some embodiments, a template can control operation of correlation engine 701, comparison engine 703, and how results are displayed on a user interface. Flowcharts illustrating different examples of the correlation analysis and comparison analysis are shown in FIG. 16, FIG. 17 and FIG. 18.

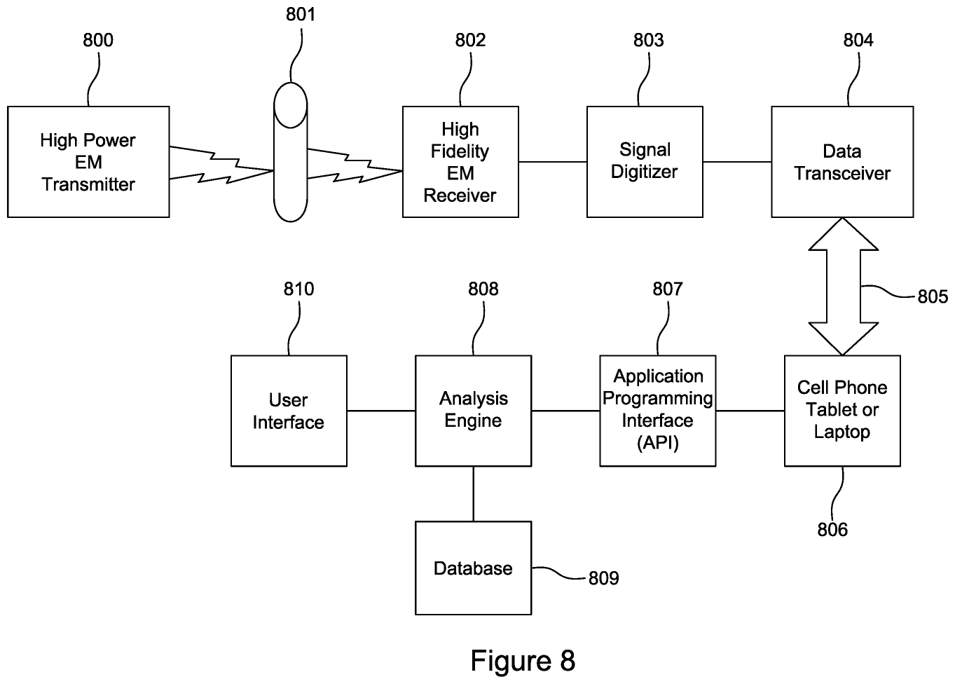

FIG. 8 shows an overview of the entire system where items 800 through 804 are the blocks associated with the NMR apparatus (e.g., FIGS. 1-3), item 805 indicates the communication conduit between the NMR apparatus and remote device, items 806 through 810 are an overview of the blocks shown the remote device (e.g., FIGS. 4-7). A High Power EM Transmitter 800 energizes the sample 801 within the magnetic chamber with a short EM pulse and then is disconnected and powered down. At a time later, the length of which is determined by various factors due to the interaction of the sample and its environment, the sample emits its first relaxation pulse which is sensed by the High Fidelity EM Receiver (e.g., FIG. 2). The frequencies of that emitted pulse are converted into a digital representation using a Signal Digitizer 803 and stored in a memory system. At the request of the remote device, the stored data is transmitted 805 to remote device 806 using a data transceiver 804. The data can be presented to the Analysis Engine 808 through an Application Programming Interface 807. The Analysis Engine analyzes the sample's data using software and hardware acceleration, if available, and a database 809. The results are then provided to the user interface 810 in a simplified format that is focused on specific template target(s).

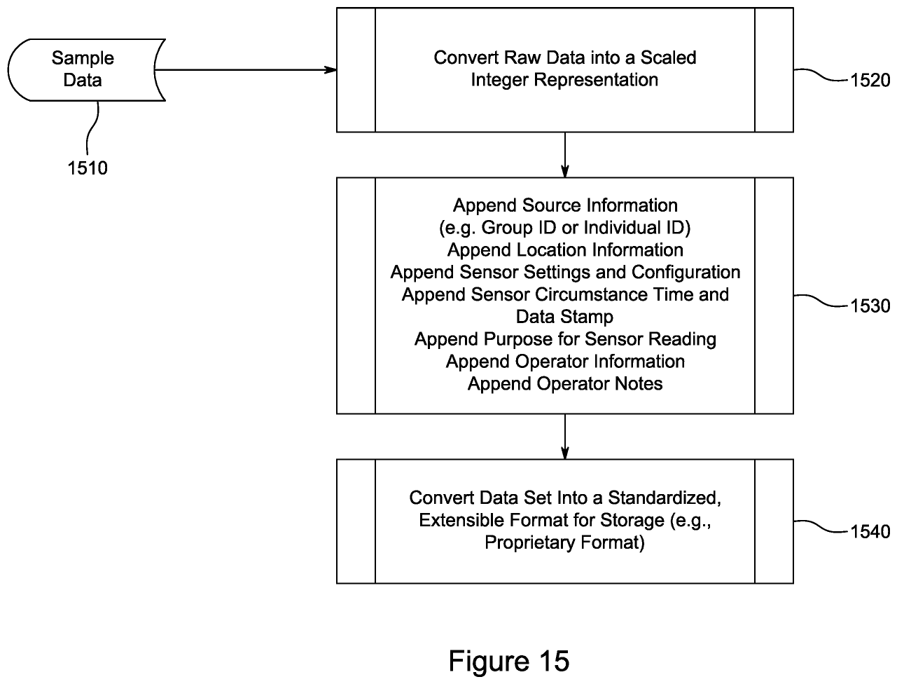

The remote device can use an API to convert data received from any NMR apparatus into a form that can be used by an analysis engine. FIG. 15 shows an illustrative API flowchart according to an embodiment. Sample data 1510 can represent the digital data that has been obtained as part of sampling event in an NMR apparatus. At step 1520, the sample data can be converted into scaled integer representations of the sample data. At step 1530, various information related to the sample data can be included in a header or other packet that is associated with the scaled integer representation. For example, source information (e.g., a group identifier or an individual identifier), location information, sensor settings and configuration information, time and date stamp of the sample information, purpose of sensor reading, operator notes, operator information, etc. At step 1540, the packet information and converted raw data can be normalized to adhere to a standardized, extensible format or a proprietary format for storage.

The remote device can have or have access to an NMR characteristics database for all compounds—organic or inorganic—elements, and substances of interest. This database can be updated automatically from a remote database of NMR characteristics as new compound characteristics are determined. The NMR characteristics database can include templates that are designed specifically to identify a specific compound, elements, or substance of interest. Some of these templates may be provided as native templates and other templates may be provided by third parties via an e-commerce platform (e.g. application store).

The remote device can use a template to define the analysis to be performed on the NMR data for the presentation to the user. A template can be a configuration file that contains a set of filters to reduce the data of organic compounds from the NMR characteristics database that are used in an analysis. The template can contain a set of characteristics that are used in an analysis. The template can contain procedure definitions for use in the analysis. The template can contain audio definitions to be used with the remote device's language engine (or other processor) to enhance the analysis process using that hardware acceleration. The template can include procedure definitions that are used by a correlation engine to associate the analysis results with specific conditions. The template can contain procedure definitions that are used by the comparison engine to associate those conditions with the history of results from a specific subject. The template can include procedure definitions to present the results of the analysis to the user in a simplified format relevant to the specific metabolic condition that the template is implemented to describe.

Data received from the NMR apparatus and processed through the API can be converted to an internal data format that increases the efficiency of the correlation engine. The internal data format enables procedure definitions included within the template to have a standardized format with which to read and transform. The mechanism to convert from received NMR data to the internal format is done either using the computational ability of the remote device or using the audio (FIG. 17) or GPU accelerators of the remote device for higher performance.

In one example of the development, the internal data format can be analyzed by a correlation engine using a database of metabolic conditions to determine the existence or magnitude of the specific metabolic condition. In another example of the development, the results of the correlation engine can be used by a comparison engine which uses a database of a sample's history to determine the differentials of that specific metabolic condition for that sample's history. All stored subject data can be encrypted according to United States' HIPAA standards.

The results of the correlation or comparison engines can be displayed in a simplified format for the user according to the definition of that presentation determined by the template. For example, the main display for the user can be a simple graph shown, but not limited to, a linear format, an exponential format, a standard Gaussian bell shaped curve. The graph can be colored to indicate a good/bad or low/medium/high range of results. A number can be presented that would be formatted and ranged according to the specific metabolic result being targeted. More detailed information can be provided by the user interface dependent upon the definition provided by the template in other displays.

The remote device can store set of templates that can be applied to the NMR data to yield results related to different, specific metabolic conditions that are the target of each of those templates. The user can select which of the stored templates can be applied to the data received from the NMR apparatus. The user can access third party templates, if desired. In some embodiments, users can create templates in a template creator. The template creator can be used by untrained individuals to create new templates.

The raw digital data for each sample can be saved in the historical database so that other templates can be used to determine other metabolic conditions or determine other patterns of metabolic changes that can be displayed for the user at any time.

FIG. 16 shows an illustrative process of using a template to enable a correlation engine to evaluate data from a NMR sample according to an embodiment. Each template can include various descriptors shown here as template filter descriptor 1611, template scoring descriptor 1621, template fingerprint descriptor 1631, and template display descriptor 1641. After NMR data has been converted to an internal format, at step 1601, the data can be applied to a data transform, at step 1602, and the transformed data can be filtered based on template filter descriptor 1611 at step 1610. The filtered data can be scored using template scoring descriptor 1621 at step 1620. At step 1630, fingerprints of the scored data can be created using template fingerprint descriptor 1631. At step 1640, the fingerprints can be converted into a displayable representation based on template display descriptor 1641. At step 1650, the results of steps 1620, 1630, and 1640 can be displayed.

It should be understood that the steps shown in FIG. 16 are merely illustrative and that additional steps may be added, some steps may be omitted, and the order the steps may be rearranged.

FIG. 17 shows another illustrative process of using a template to enable a correlation engine to evaluate data from a NMR sample according to an embodiment. FIG. 17 is similar to FIG. 16, but uses the sampled data in an audio data format to enable a correlation engine to analyze the data in accordance with template parameters. Each template can include various descriptors shown here as template language descriptor 1711, template language/scoring descriptor 1721, template fingerprint descriptor 1731, and template display descriptor 1741. After NMR data has been converted to an internal format, at step 1701, the data can be applied to an audio data transform, at step 1702, and the audio data can be applied to voice recognition software to generates words defined within template language descriptor 1711 at step 1710. The words can be scored using template language/scoring descriptor 1721 at step 1720. At step 1730, fingerprints of the scored data can be created using template fingerprint descriptor 1731. At step 1740, the fingerprints can be converted into a displayable representation based on template display descriptor 1741. At step 1750, the results of steps 1720, 1730, and 1740 can be displayed.

It should be understood that the steps shown in FIG. 17 are merely illustrative and that additional steps may be added, some steps may be omitted, and the order the steps may be rearranged.

FIG. 18 shows a flowchart for the process for comparing specific NMR results with historical data to determine trends over time according to an embodiment. A template can define comparison descriptors to control how current data is compared to historical data. As shown, the template can include template merging descriptor 1811, template trend vector descriptor 1821, and template display descriptor 1831. NMR data, which can be represented in an internal format, can be provided at step 1801. The data at step 1801 may be the results obtained by a correlation engine. At step 1810, new results from step 1801 may be merged with historical results according to template merging descriptor 1811. At step 1820, a trend can be calculated for the merged results according to template trend vector descriptor 1821. At step 1830, the trend results may be converted into a displayable representation per requirements of template display descriptor 1831. The display representation can be displayed at step 1840.

It should be understood that the steps shown in FIG. 18 are merely illustrative and that additional steps may be added, some steps may be omitted, and the order the steps may be rearranged.

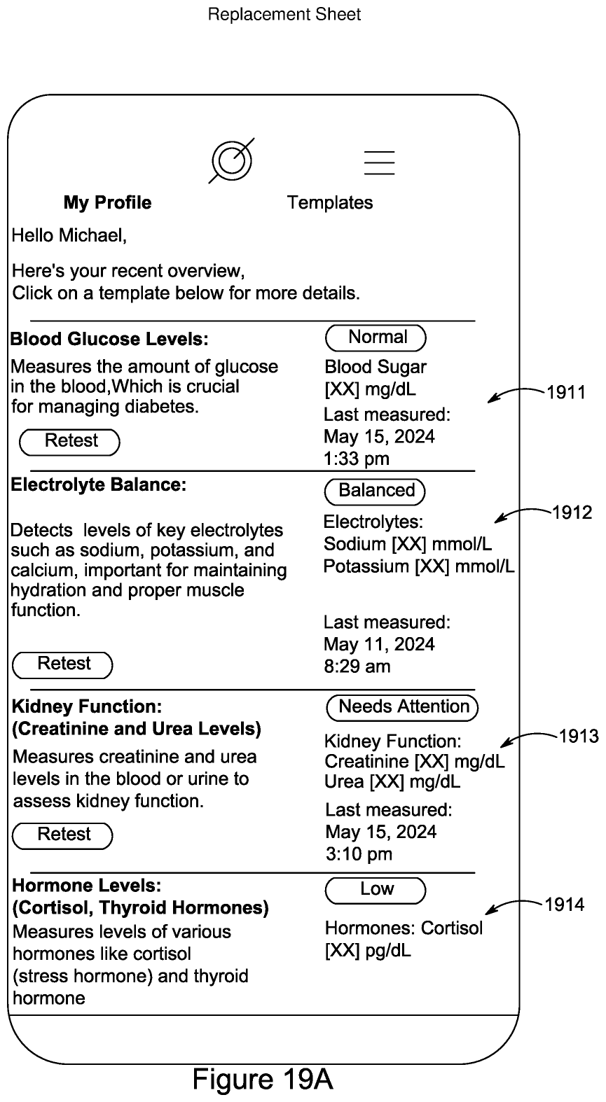

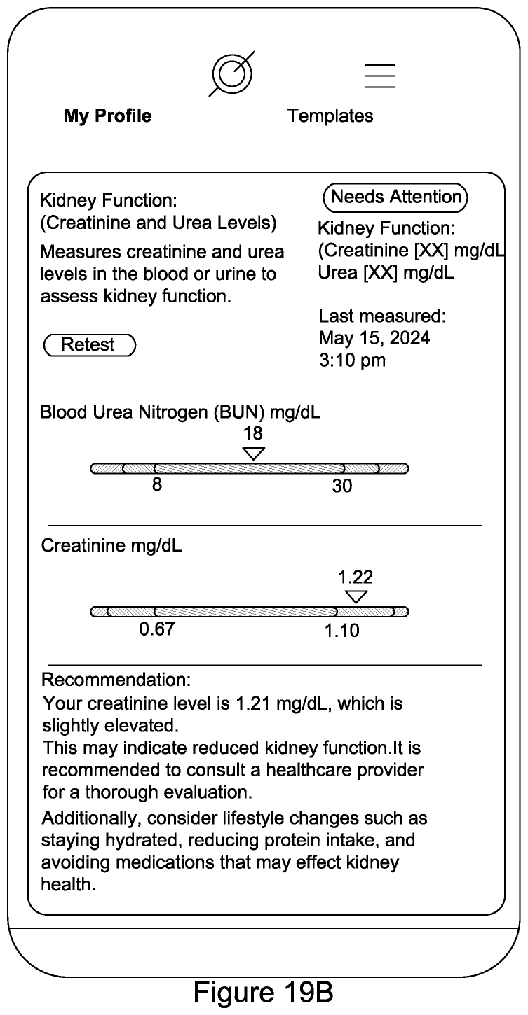

FIGS. 19A and 19B show illustrative screen shots of a user interface that may be presented on a remote device that has analyzed NMR data received from an NMR device according to an embodiment. In particular, FIG. 19A shows an overview of results obtained from a sample belonging to a particular user. The overview shows multiple panels 1911-1914 that each correspond to a particular evaluation criteria, shown here as blood glucose panel 1911, electrolyte balance panel 1912, kidney function panel 1913, and hormone levels panel 1914. Each panel can include a definition, data pertaining to the panel, and a text and visual indicator to succinctly convey the status of the panel. For example, the definition can explain what is being tested. The data pertaining to the panel can include a test date and actual test numbers typically designated for that panel. For example, for blood glucose, this can be expressed as mg/dL. The text and visual indicator specify whether the test was normal, low, high, or needs attention in highlighted color corresponds to the text description. For example, normal may be shown in green, needs attention may be shown in yellow, and low and high may be shown in red. A user can select any panel to bring up a more detailed user interface screen, such as that shown in FIG. 19B.

FIG. 19B shows a more detailed screen shot corresponding to kidney function, for example. The more detailed screen shot can provide a graphical bar showing where the results of the sample fall. For example, blood urea nitrogen is shown to exist in the green/good region whereas creatinine is shown to be in the yellow/attention needed region. It should be appreciated that display embodiments disclosure herein presents what has conventionally been difficult to decipher NMR data in an easy to read and understandable context. This is made possible with the use of templates that are designed to specifically identify each panel subject (e.g., shown in FIG. 19A as blood glucose, electrolyte balance, kidney function, and hormone levels) in NMR data obtained from the NMR apparatus and present the results in accordance with the template.

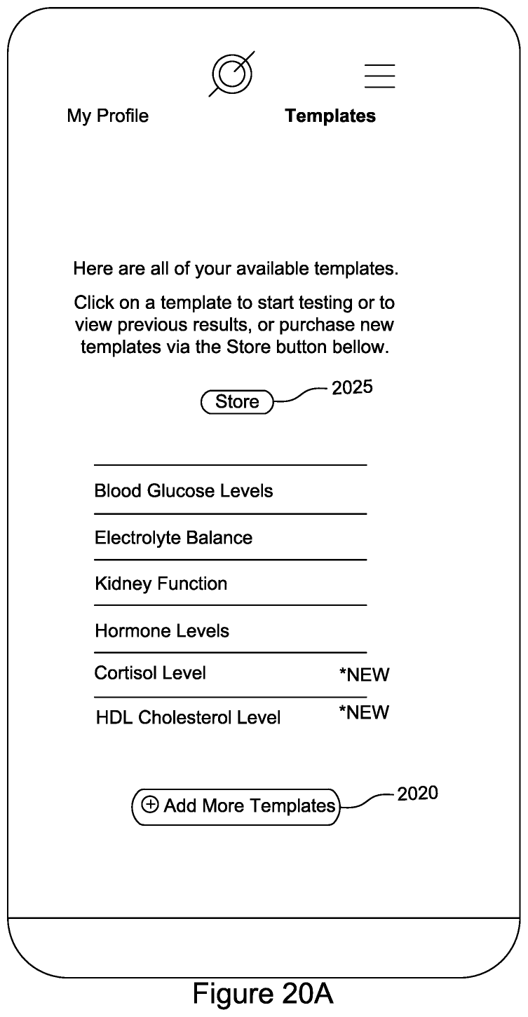

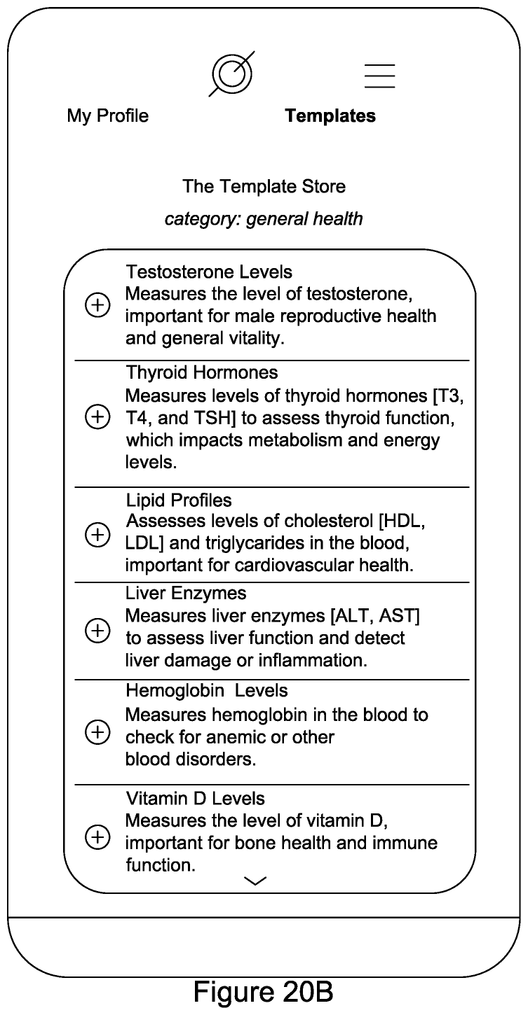

FIG. 20A shows a user interface screen listing templates that are available to be used by the user. The user can select any of the displayed templates to start testing or view previous results. If desired, the user can add more templates by selecting add more templates icon 2020 or shop for more templates by accessing store icon 2025. If the user selects add more templates icon 2020, the user may be presented with templates that are available or have been previously purchased. If the user selects store icon 2025, the user may be presented with a user interface shown in FIG. 20B. FIG. 20B shows a store front with many templates available for purchase or download. The user can select any one of more the templates as desired.

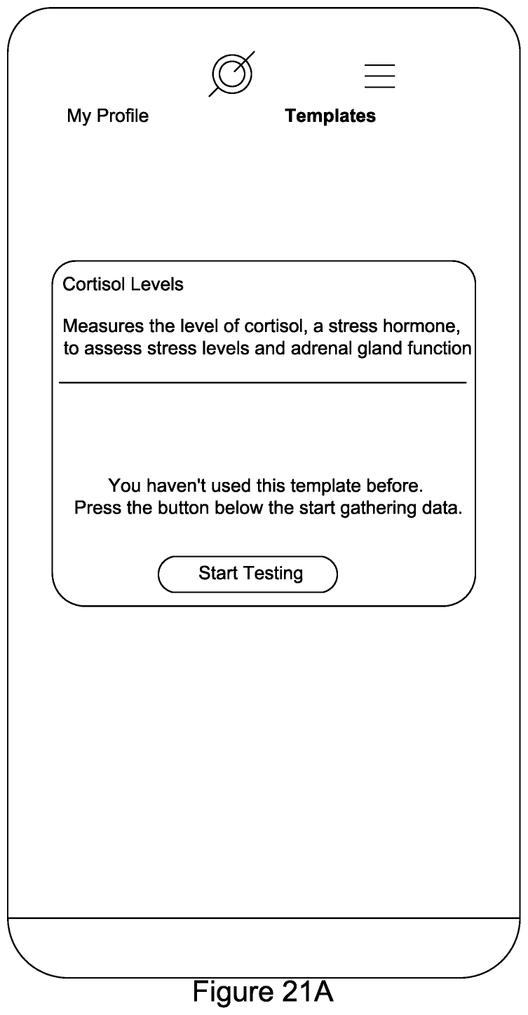

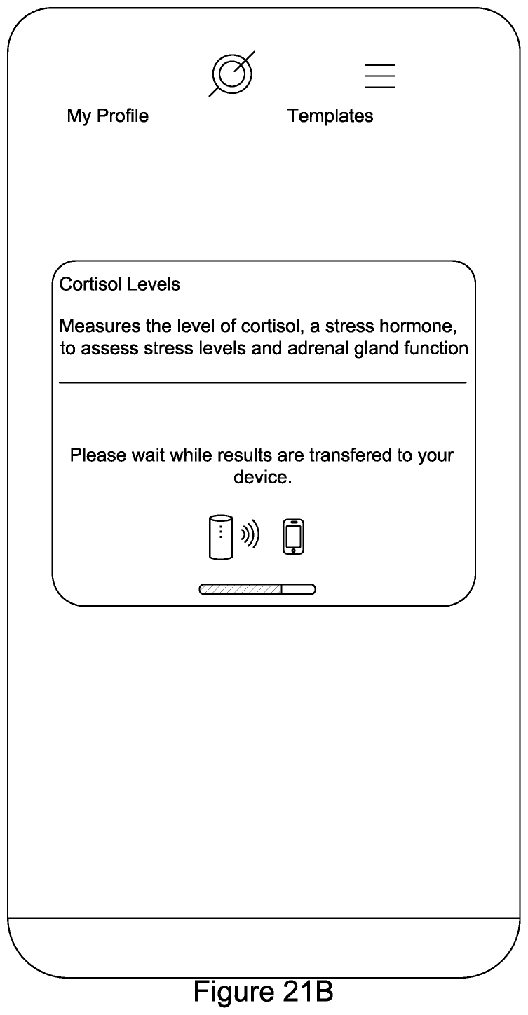

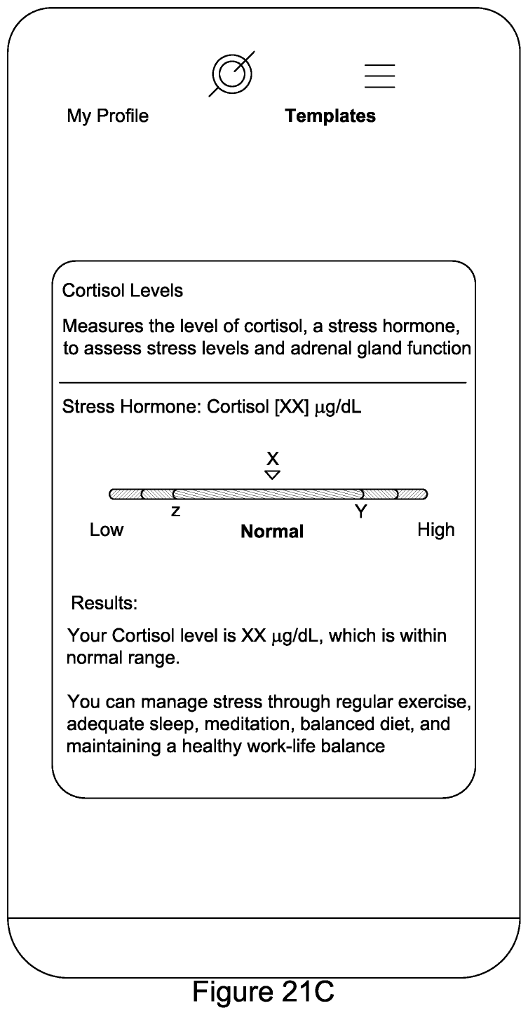

FIGS. 21A-21C shows an illustrative sequence of screen shots that may be presented to the user as part of testing flow according to an embodiment. Starting with FIG. 21A, a user is presented with a user interface screen to start testing his or her cortisol levels. FIG. 21B shows a user interface screen indicating data is being transferred from a NMR apparatus to the user's device. FIG. 21C shows a result screen showing the results of the correlation engine's analysis of the NMR data provided by the NMR apparatus. As shown, the results are presented in an easy to ready graphical format that does not require advance technical knowledge of parsing NMR data; the template provides a basis for the correlation engine to evaluate the data with a high degree of accuracy and present the results.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory. Memory may be implemented within the processor or external to the processor. As used herein the term “memory” refers to any type of long term, short term, volatile, nonvolatile, or other storage medium and is not to be limited to any particular type of memory or number of memories, or type of media upon which memory is stored.

Moreover, as disclosed herein, the term “storage medium” may represent one or more memories for storing data, including read only memory (ROM), random access memory (RAM), magnetic RAM, core memory, magnetic disk storage mediums, optical storage mediums, flash memory devices, Internet connected Cloud storage and/or other machine readable mediums for storing information. The term “machine-readable medium” includes, but is not limited to portable or fixed storage devices, optical storage devices, wireless channels, and/or various other storage mediums capable of storing that contain or carry instruction(s) and/or data.

Having described several embodiments, it will be recognized by those of skill in the art that various modifications, alternative constructions, and equivalents may be used without departing from the spirit of the development. Additionally, a number of well-known processes and elements have not been described in order to avoid unnecessarily obscuring the present development. Accordingly, the above description should not be taken as limiting the scope of the development.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the development, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the device” includes reference to one or more devices and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A portable and battery powered nuclear magnetic resonance (NMR) apparatus, comprising:
a housing configured to receive a sample vessel, the housing comprising:
a magnetic assembly comprising an open cylindrical hole positioned in a center axis of the magnetic assembly;
an antenna assembly comprising two antenna directors that extend into the open cylindrical hole and are configured to receive the sample vessel, wherein the two antenna directors collectively form two halves of a hollow columnar antenna array with a gap existing between each half of the array and which have a center axis that is substantially co-aligned with the center axis of the magnetic assembly, wherein when the sample vessel is inserted into the housing, the sample vessel is positioned within the hollow columnar antenna array and the open cylindrical hole;
transmitter circuitry operative to radiate an electromagnetic (EM) signal, via the antenna assembly, to a sample contained in the sample vessel;
receiver circuitry operative to receive, via the antenna assembly, re-radiated EM energy emanating from the sample as NMR data; and
control circuitry operative to store a digital version of the NMR data in memory.

2. The NMR apparatus of claim 1, wherein an orientation of the two antenna directors is arranged such that an electric field generated by the antenna array is substantially orthogonal to a magnetic field provided by the magnet assembly.

3. The NMR apparatus of claim 1, wherein the magnet assembly is a Halbach Array.

4. The NMR apparatus of claim 1, further comprising a motor assembly configured to rotate the sample vessel during a sample event.

5. The NMR apparatus of claim 1, further comprising communications circuitry operative to transmit the NMR data stored in the memory to a remote device that processes the NMR data through a data analysis engine to determine whether the sample contains a marker or markers of interest.

6. The NMR apparatus of claim 1, further comprising:
a battery; wherein the transmitter circuitry comprises:
power supply circuitry coupled to the battery and operative to boost a battery supply voltage to an antenna excitation voltage for an EM transmission event; and
a spread spectrum oscillator operative to provide a resonant frequency for the EM transmission event.

7. The NMR apparatus of claim 1, wherein the control circuitry is operative to:
control power on and power off sequencing of the transmitter circuitry and the receiver circuitry;
control first switch sequencing to connect and disconnect the antenna assembly to the transmitter circuitry; and
control second switch sequencing to connect and disconnect the antenna assembly to the receiver circuitry.

8. The NMR apparatus of claim 1, wherein the magnet assembly comprises a magnetic field ranging between 1.4 Tesla and 3.0 Tesla, and wherein the EM signal comprises up to one kilowatt of energy.

9. A method for processing nuclear magnetic resonance (NMR) data of a sample, the method implemented in a computer device, the method comprising:
receiving digital NMR data from a portable NMR apparatus;
transforming the digital NMR data to transformed NMR data;
processing the transformed NMR data through a data analysis engine in accordance with a template that focuses analysis of the transformed NMR data to a template specific target existing in the sample; and
displaying results of the processing in accordance with a display descriptor associated with the template.

10. The method of claim 9, wherein the transformed NMR data exists in an internal format; and
wherein the processing further comprises correlating the transformed NMR data with a database to generate results for the template specific target.

11. The method of claim 9, wherein the transformed NMR data exists in an audio data format; and
wherein the processing further comprises:
using an audio processor to identify words in the transformed NMR data based on a language descriptor associated with the template;
scoring the identified words based on a language/score descriptor associated with the template;
creating a fingerprint of the scored words based on a fingerprint descriptor associated with the template; and
converting the fingerprint to a displayable representation based on the display descriptor.

12. The method of claim 9, wherein the processing further comprises:
comparing the results to a historical database to determine trends for the template specific target existing in the sample.

13. The method of claim 9, wherein the template is one of a plurality of templates that provide descriptors for a plurality of template specific targets.

14. The method of claim 13, wherein the processing comprises generating and displaying results for each of the plurality of templates.

15. The method of claim 13, further comprising:
enabling a user to download or purchase a new template to be applied to the transformed NMR data.

16. The method of claim 9, wherein the template specific target is a specific metabolic condition, a specific compound, or a specific element.

17. A system comprising:
a portable and battery powered nuclear magnetic resonance (NMR) apparatus configured to receive a sample vessel, irradiate a sample contained in the sample vessel with electromagnetic (EM) energy, capture re-radiated EM energy emanating from the sample as NMR data, store the NMR data in memory, and transmit the NMR data stored in the memory; and
an application operating on a device communicatively coupled to receive the transmitted NMR data from the portable and battery powered NMR apparatus and configured to transform the NMR data to transformed NMR data, analyze the transformed NMR data in accordance with at least one template and display analysis results thereof, wherein each template defines how a correlation engine evaluates the transformed NMR data to assess whether a template target exists in the sample.
